(19) United States
(12) Patent Application Publication
(10) Pub. No.: US 2025/0234682 A1
(43) Pub. Date: Jul. 17, 2025

(54) LIGHT-EMITTNG DEVICE STRUCTURE, DISPLAY APPARATUS INCLUDING THE SAME, AND METHOD OF MANUFACTURING LIGHT-EMITTING DEVICE STRUCTURE

(71) Applicant: Samsung Electronics Co., Ltd., Suwon-si (KR)

(72) Inventors: Sunil KIM, Suwon-si (KR); Junhee Choi, Suwon-si (KR); Nakhyun Kim, Suwon-si (KR)

(73) Assignee: Samsung Electronics Co., Ltd., Suwon-si (KR)

(21) Appl. No.: 18/811,066

(22) Filed: Aug. 21, 2024

(30) Foreign Application Priority Data
Jan. 17, 2024 (KR) 10-2024-0007639

(51) Int. Cl. H01L 33/20; H01L 25/075; H01L 33/00; H01L 33/38; H01L 33/46; H01L 33/50

(52) U.S. Cl. CPC H10H 20/819; H01L 25/0753; H10H 20/01; H10H 20/8316; H10H 20/841; H10H 20/851; H10H 20/032; H10H 20/0361

(57) ABSTRACT

Provided are a display apparatus including a light-emitting device structure, and a method of manufacturing same. The light-emitting device structure includes: a substrate; a semiconductor device layer on the substrate and including semiconductor devices; and a display device layer including light-emitting rods on the semiconductor device layer and connected to the semiconductor devices, wherein the light-emitting rods include: first, second, and third light-emitting rods configured to respectively emit light having first, second, and third wavelengths, wherein each of the light-emitting rods includes a first type semiconductor layer, an active layer, and a second type semiconductor layer, which are sequentially arranged, and wherein, in at least one of the light-emitting rods, the first type semiconductor layer includes a pore containing a wavelength conversion cluster configured to convert light generated from the active layer into light having a wavelength different from the light generated from the active layer.

### CROSS-REFERENCE TO RELATED APPLICATION

This application is based on and claims priority to Korean Patent Application No. 10-2024-0007639, filed on Jan. 17, 2024, in the Korean Intellectual Property Office, the disclosure of which is incorporated by reference herein in its entirety.

### BACKGROUND

### 1. Field

The disclosure relates to a light-emitting device structure, a display apparatus including the same, and a method of manufacturing the light-emitting device structure.

### 2. Description of the Related Art

Compared to the existing light sources, next generation light source devices have the advantage of longer lifespan, lower power consumption, faster response speed, improved environmental-friendliness, etc., and have been used in various products including lighting systems, as a backlight of a display apparatus, etc. In particular, light-emitting diodes (LEDs) based on group 3 nitrides, such as gallium nitride (GaN), aluminum gallium nitride (AlGaN), indium gallium nitride (InGaN), indium aluminum gallium nitride (InAlGaN), etc., have functioned as semiconductor light-emitting devices for light emission.

### SUMMARY

Provided are a light-emitting device structure in which a plurality of light-emitting devices emitting light of different wavelengths from each other are arranged on one substrate or panel, and quantum dots are encapsulated in some of the light-emitting devices, a display apparatus including the light-emitting device structure, and a method of manufacturing the light-emitting device structure.

Additional aspects will be set forth in part in the description which follows and, in part, will be apparent from the description, or may be learned by practice of the presented embodiments of the disclosure.

According to an aspect of the disclosure, a light-emitting device structure includes: a substrate; a semiconductor device layer on the substrate, the semiconductor device layer including a plurality of semiconductor devices; and a display device layer including a plurality of light-emitting rods on the semiconductor device layer, wherein the plurality of light-emitting rods are connected to the plurality of semiconductor devices, wherein the plurality of light-emitting rods includes: a first light-emitting rod configured to emit light including a first wavelength; a second light-emitting rod configured to emit light including a second wavelength which is different from the first wavelength; and a third light-emitting rod configured to emit light including a third wavelength which is different from the first wavelength and the second wavelength, wherein each of the plurality of light-emitting rods includes a first type semiconductor layer, an active layer, and a second type semiconductor layer, which are sequentially arranged, and wherein, in at least one of the plurality of light-emitting rods, the first type semiconductor layer includes a pore, and a wavelength conversion cluster in the pore, wherein the wavelength conversion cluster is configured to convert light generated from the active layer into light having a wavelength different from a wavelength of the light generated from the active layer.

Each of the plurality of light-emitting rods may be in an upright position corresponding to a thickness direction of the substrate, the display device layer may further include a bank layer including a groove, and at least a part of each of the plurality of light-emitting rods may be in the groove.

Each of the plurality of light-emitting rods may include a first diameter and a first height, the groove may include a first width and a second height, and the first width may be greater than the first diameter, and the second height may be greater than one-fourth of the first height.

The light-emitting device structure may further includes: a lower electrode connected to a lower portion of each of the plurality of light-emitting rods; and an upper electrode connected to an upper portion of each of the plurality of light-emitting rods.

The light-emitting device structure may further include a contact electrode in contact with the lower electrode and each of the plurality of light-emitting rods, wherein the contact electrode includes a first contact portion in contact with a lateral surface of the groove, a second contact portion in contact with an upper surface of the lower electrode, and a third contact portion in contact with a lower lateral surface of each of the plurality of light-emitting rods.

The bank layer may further include an insulating layer in the groove, and the insulating layer may be configured to maintain the upright position of each of the plurality of light-emitting rods.

A portion of each of the plurality of light-emitting rods may partially protrude from an upper surface of the insulating layer, and the upper electrode may be in contact with the portion of each of the plurality of light-emitting rods protruding from the upper surface of the insulating layer.

For each of the plurality of light-emitting rods, the first type semiconductor layer may be on the active layer, and each of the plurality of light-emitting rods may further include a reflective layer under the second type semiconductor layer.

The light-emitting device structure may further include: a color filter configured to selectively transmit light, and the color filter may be on at least one of the plurality of light-emitting rods.

The light-emitting device structure may further include: a wavelength selective transmissive layer configured to selective transmit light according to a wavelength, wherein the wavelength selective transmissive layer is on a lateral surface of at least one of the plurality of light-emitting rods.

For each of the plurality of light-emitting rods, a ratio of a length of the light-emitting rod to a width of the light-emitting rod may be 3 or more, and the width may be 100 μm or less.

According to an aspect of the disclosure, a display apparatus includes: a plurality of light-emitting device structures, wherein each of the plurality of light-emitting device structures includes: a substrate; a semiconductor device layer on the substrate, the semiconductor device layer including a plurality of semiconductor devices; a display device layer including a plurality of light-emitting rods on the semiconductor device layer, wherein the plurality of light-emitting rods are connected to the plurality of semiconductor devices; a lower electrode connected to a lower portion of each of the plurality of light-emitting rods; and an upper electrode connected to an upper portion of each of the plurality of light-emitting rods, wherein the plurality of light-emitting rods includes: a first light-emitting rod configured to emit light including a first wavelength; a second light-emitting rod configured to emit light including a second wavelength which is different from the first wavelength; and a third light-emitting rod configured to emit light including a third wavelength which is different from the first wavelength and the second wavelength, wherein each of the plurality of light-emitting rods includes a first type semiconductor layer, an active layer, and a second type semiconductor layer, which are sequentially arranged, wherein, in at least one of the plurality of light-emitting rods, the first type semiconductor layer includes a pore and a wavelength conversion cluster in the pore, and wherein the wavelength conversion cluster is configured to convert light generated from the active layer into light having a wavelength different from a wavelength of the light generated from the active layer.

For each of the plurality of light-emitting device structures, the display device layer may further include a bank layer including a groove, and at least a part of each of the plurality of light-emitting rods may be in the groove.

For each of the plurality of light-emitting device structures, the bank layer may further include an insulating layer in the groove, and the insulating layer may be configured to maintain each of the plurality of light-emitting rods in an upright position corresponding to a thickness direction of the substrate.

For each of the plurality of light-emitting rods of each of the plurality of light-emitting device structures, the first type semiconductor layer may be on the active layer, and each of the plurality of light-emitting rods may further include a reflective layer under the second type semiconductor layer.

Each of the plurality of light-emitting device structures may further include: a wavelength selective transmissive layer configured to selective transmit light according to a wavelength, wherein the wavelength selective transmissive layer is on a lateral surface of at least one of the plurality of light-emitting rods.

For each of the plurality of light-emitting device structures, each of the plurality of light-emitting rods may include a first diameter and a first height, the groove may include a first width and a second height, and the first width may be greater than the first diameter, and the second height may be greater than one-fourth of the first height.

According to an aspect of the disclosure, a method of manufacturing a light-emitting device structure includes: arranging a plurality of light-emitting rods on a semiconductor device layer provided on a substrate; aligning the plurality of light-emitting rods in a first direction by applying an electric field around the plurality of light-emitting rods; and connecting the plurality of light-emitting rods to an electrode, wherein at least one of the plurality of light-emitting rods includes a first type semiconductor layer including a pore, and a wavelength conversion cluster in the pore, and wherein the wavelength conversion cluster is configured to convert light generated from an active layer of the at least one of the plurality of light-emitting rods into light having a wavelength different from a wavelength of the light generated from the active layer.

The arranging the plurality of light-emitting rods on the semiconductor device layer includes applying a liquid including the plurality of light-emitting rods on a bank layer including a groove configured to receive the plurality of light-emitting rods, and wherein the aligning the plurality of light-emitting rods may further include arranging the plurality of light-emitting rods in the groove in an upright position corresponding to a thickness direction of the substrate using the electric field.

The connecting the plurality of light-emitting rods to the electrode may include: forming a contact electrode in contact with a lower portion of the plurality of light-emitting rods and a lower electrode connected to a semiconductor device of the semiconductor device layer; filling the groove with an insulating layer which covers the contact electrode; and forming an upper electrode connected to an upper portion of each of the plurality of light-emitting rods.

According to an aspect of the disclosure, a light-emitting device structure includes: a semiconductor device layer including a plurality of semiconductor devices; and a display device layer including a plurality of light-emitting rods on the semiconductor device layer, wherein the plurality of light-emitting rods includes: a first light-emitting rod configured to emit red light; a second light-emitting rod configured to emit green light; and a third light-emitting rod configured to emit blue light, wherein each of the plurality of light-emitting rods includes a quantum well, at least one of the first light-emitting rod, the second light-emitting rod, and the third light-emitting rod includes quantum dots, and at least one of the first light-emitting rod, the second light-emitting rod, and the third light-emitting rod lacks quantum dots, and wherein the plurality of light-emitting rods extends in a same direction.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a light-emitting device structure according to an embodiment;

FIGS. 2 and 3 are each a schematic cross-sectional view of each of a plurality of light-emitting rods of FIG. 1;

FIG. 4 is an enlarged view of a part of the light-emitting device structure of FIG. 1, according to an embodiment;

FIG. 5 is another enlarged view of a part of the light-emitting device structure of FIG. 1, according to an embodiment;

FIG. 6 is a schematic cross-sectional view of a light-emitting device structure according to another embodiment;

FIG. 7 is a schematic cross-sectional view of a light-emitting device structure according to another embodiment;

FIG. 8 is a flowchart illustrating a method of manufacturing a light-emitting device structure according to an embodiment;

FIGS. 9A, 9B, 90, 9D and 9E are each a view illustrating a method of manufacturing a light-emitting device of a light-emitting device structure, according to an embodiment;

FIG. 10 is a plan view illustrating a process of applying and aligning a plurality of light-emitting nanorods on a substrate;

FIG. 11 is a cross-sectional view taken along line XI-XI′ line of FIG. 10; and

FIGS. 12A, 12B and 12C are each a view illustrating a process of connecting an electrode to a light-emitting rod in a light-emitting device structure, according to an embodiment.

### DETAILED DESCRIPTION

Reference will now be made in detail to one or more embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Expressions such as “at least one of,” when preceding a list of elements, modify the entire list of elements and do not modify the individual elements of the list. For example, as used herein, the expressions “at least one of a, b or c” and “at least one of a, b and c” indicate “only a,” “only b,” “only c,” “both a and b,” “both a and c,” “both b and c,” and “all of a, b, and c.”

Hereinafter, example embodiments will be described in detail with reference to the accompanying drawings. In the drawings, like reference numerals in the drawings denote like elements, and sizes of components in the drawings may be exaggerated for clarity and convenience of explanation. Embodiments described below are provided only as an example, and thus can be embodied in various forms.

It will be understood that when a component is referred to as being “on” or “over” another component, the component can be directly on, under, on the left of, or on the right of the other component, or can be on, under, on the left of, or on the right of the other component in a non-contact manner. An expression used in the singular encompasses the expression of the plural, unless it has a clearly different meaning in the context. When a portion “includes” an element, another element may be further included, rather than excluding the existence of the other element, unless otherwise described.

The use of the terms “a” and “an” and “the” and similar referents in the context of describing embodiments (especially in the context of the following claims) are to be construed to cover both the singular and the plural. The operations of all methods described herein can be performed in any suitable order unless otherwise indicated herein or otherwise clearly contradicted by context, and embodiments are not limited to the described order of the operations.

Moreover, the terms “part,” “module,” etc. refer to a unit processing at least one function or operation, and may be implemented by a hardware, a software, or a combination thereof.

The connecting lines, or connectors shown in the various figures presented are intended to represent exemplary functional relationships and/or physical or logical couplings between the various elements, and thus it should be noted that many alternative or additional functional relationships, physical connections or logical connections may be present in a practical device.

The use of any and all examples, or exemplary language provided herein, is intended merely to better illuminate technical ideas and does not pose a limitation on the scope of embodiments unless otherwise claimed.

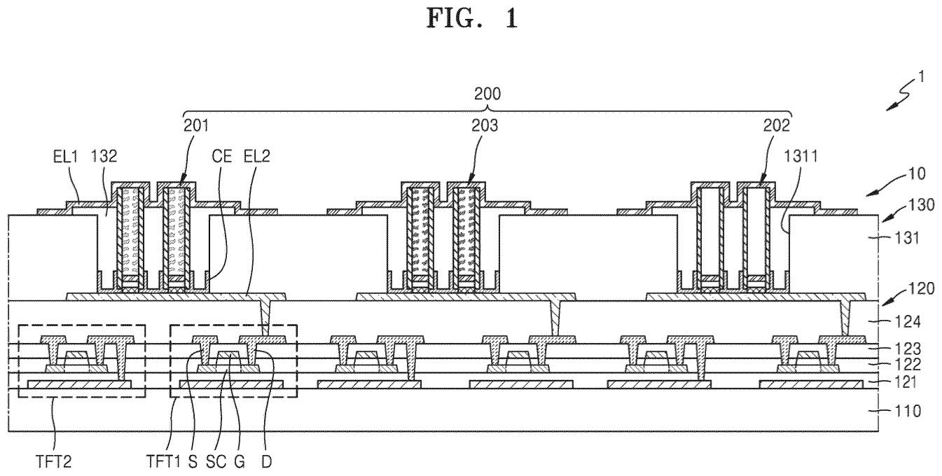

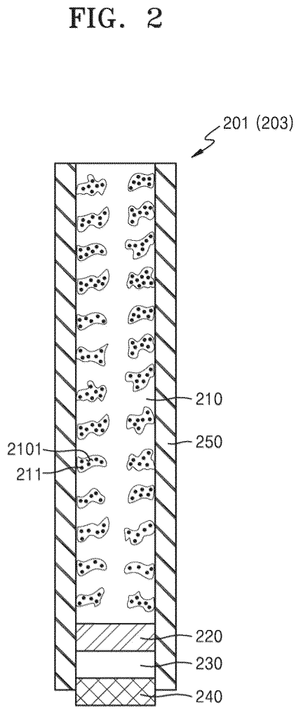

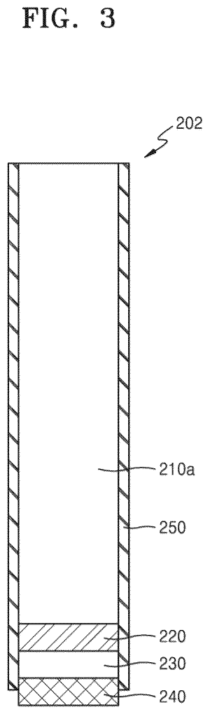

FIG. 1 is a schematic cross-sectional view of a light-emitting device structure 10 according to an embodiment, and FIGS. 2 and 3 are each a schematic cross-sectional view of each of a plurality of light-emitting rods 200 of FIG. 1.

Referring to FIG. 1, a display apparatus 1 according to an embodiment may include the light-emitting device structure 10. The display apparatus 1 may include one light-emitting device structure 10 or a plurality of light-emitting device structures 10. The display apparatus 1 may be applied to various apparatuses through a bottom-up assembly using the light-emitting device structure 10. The display apparatus 1 may be a television (TV), an augmented reality (AR) apparatus, a virtual reality (VR) apparatus, or a mixed reality (MR) apparatus or may be used in such apparatuses.

The light-emitting device structure 10 may include a substrate 110, a semiconductor device layer 120 arranged on the substrate 110, and a display device layer 130 arranged on the semiconductor device layer 120.

The substrate 110 may be a single substrate. The substrate 110 may include an insulating material. For example, the substrate 110 may include glass, organic polymer, crystal, etc. However, the foregoing materials of the substrate 110 are only an example, and various other materials may be used as the substrate 110. The substrate 110 may include a material having flexibility such that the substrate 110 may be bent or folded. The substrate 110 may include a single layer or a plurality of layers in which different materials are stacked.

The semiconductor device layer 120 may include at least one semiconductor device. In this regard, the semiconductor device may include, for example, at least one of a transistor, a capacitor, a diode, and a resistor. However, the type of the semiconductor device is not limited thereto.

For example, the semiconductor device layer 120 may include a plurality of transistors. Each of the plurality of transistors may drive a corresponding light-emitting rod 200 from among the plurality of light-emitting rods 200. The transistor may include a semiconductor layer SC, a gate electrode G, a source electrode S, and a drain electrode D.

The semiconductor layer SC may be arranged on a buffer layer 121. The semiconductor layer SC may include a source region in contact with the source electrode S, and a drain region in contact with the drain electrode D. A region between the source region and the drain region may be a channel region.

The semiconductor layer SC may be a semiconductor pattern including polysilicon, amorphous silicon, oxide semiconductor, etc. The channel region may be a semiconductor pattern undoped with impurities, e.g., an intrinsic semiconductor. The source region and the drain region may be semiconductor patterns doped with impurities.

The gate electrode G may be provided on the semiconductor layer SC with a gate insulating layer 122 therebetween. Each of the source electrode S and the drain electrode D may be in contact with the source region and the drain region of the semiconductor layer SC through a contact hole penetrating an interlayer insulating layer 123 and the gate insulating layer 122. A protective layer 124 may be provided on the plurality of transistors.

The plurality of transistors may include a plurality of driving transistors TFT1. The plurality of transistors may further include a plurality of switching transistors TFT2. The number of the plurality of driving transistors TFT1 may correspond to the number of the plurality of light-emitting rods 200. The number of the plurality of switching transistors TFT2 may correspond to the number of the plurality of light-emitting rods 200. However, the number of the plurality of driving transistors TFT1 and the number of the plurality of switching transistors TFT2 do not necessarily correspond to the number of the plurality of light-emitting rods 200 and may vary according to the need.

The display device layer 130 may include the plurality of light-emitting rods 200 arranged on the semiconductor device layer 120 to be electrically connected to the plurality of semiconductor devices.

Each of the plurality of light-emitting rods 200 may include an inorganic substance-based semiconductor material and may emit light of a particular wavelength according to a material included in the light-emitting rods 200.

The light-emitting rod 200 may include various types of micro-sized or nano-sized light-emitting diodes. For example, the width (or diameter) of the light-emitting rod 200 may be 100 μm or less or 50 μm or less. The width (or diameter) of the light-emitting rod 200 may be 1 μm or less. The width (or diameter) of the light-emitting rod 200 may be about 1 nm to about 100 μm. The light-emitting rod 200 may include a light-emitting diode (LED), a vertical-cavity surface-emitting laser (VCSEL), etc.

The plurality of light-emitting rods 200 may include light-emitting rods 200 configured to emit light having different wavelengths from each other. For example, the plurality of light-emitting rods 200 may include light-emitting rods 200 configured to emit light of different colors from each other. For example, the plurality of light-emitting rods 200 may include light-emitting rods 200 configured to emit green light, red light, and blue light. For example, the plurality of light-emitting rods 200 may include a first light-emitting rod 201, a second light-emitting rod 202, and a third light-emitting rod 203.

The first light-emitting rod 201 may emit light having a first wavelength. The second light-emitting rod 202 may emit light having a second wavelength that is different from the first wavelength. The third light-emitting rod 203 may emit light having a third wavelength that is different from the first wavelength and the second wavelength. For example, the first light-emitting rod 201 may emit green light, the second light-emitting rod 202 may emit red light, and the third light-emitting rod 203 may emit blue light. The foregoing color of light and arrangement of the first to third light-emitting rods 201, 202, and 203 are provided as an example and may vary according to the need.

As the light-emitting device structure 10 includes the first to third light-emitting rods 201, 202, and 203 respectively emitting red light, green light, and blue light on one substrate 110, the light-emitting device structure 10 may be referred to as a single panel RGB light-emitting device or a one panel RGB light-emitting device.

Referring to FIGS. 2 and 3, each of the plurality of light-emitting rods 200 may include a first type semiconductor layer 210, an active layer 220, and a second type semiconductor layer 230, which are sequentially arranged. The first type semiconductor layer 210 and the second type semiconductor layer 230 may be arranged apart from each other, and the active layer 220 may be arranged between the first type semiconductor layer 210 and the second type semiconductor layer 230.

Each of the plurality of light-emitting rods 200 may have a shape of a bar having a length greater than a width. For example, a ratio of the length to the width of the light-emitting rod 200 may be 3 or greater. For example, the ratio of the length to the width of the light-emitting rod 200 may be about 3 to about 100.

The volume of the first type semiconductor layer 210 may be greater than the volume of the active layer 220 or the volume of the second type semiconductor layer 230. The volume of the first type semiconductor layer 210 may be greater than or equal to the sum of the volume of the active layer 220 and the volume of the second type semiconductor layer 230.

The first type semiconductor layer 210 may be a semiconductor layer doped with a first conductivity type dopant. For example, the first type semiconductor layer 210 may include an n-type semiconductor, for example, n-GaN. However, the disclosure is not limited thereto, and in some cases, the first type semiconductor layer 210 may include a p-type semiconductor. The first type semiconductor layer 210 may have a single-layer or multi-layer structure. The first type semiconductor layer 210 may include, for example, InAlGaN, GaN, AlGaN, and/or InGaN, and may include a semiconductor layer doped with a dopant, such as Si, Ge, Sn, etc.

In at least some of the plurality of light-emitting rods 200, the first type semiconductor layer 210 may have a porous structure. For example, the first type semiconductor layer 210 of the first light-emitting rod 201 and the first type semiconductor layer 210 of the third light-emitting rod 203 may have a porous structure, and the first type semiconductor layer 210 of the second light-emitting rod 202 may not have a porous structure. The first type semiconductor layer 210 of the first light-emitting rod 201, the first type semiconductor layer 210 of the second light-emitting rod 202, and the first type semiconductor layer 210 of the third light-emitting rod 203 may have a porous structure. The first type semiconductor layer 210 of the first light-emitting rod 201 may have a porous structure, and the first type semiconductor layer 210a of the second light-emitting rod 202 and the first type semiconductor layer 210a of the third light-emitting rod 203 may not have a porous structure.

In at least some of the plurality of light-emitting rods 200, the first type semiconductor layer 210 may have a plurality of pores 2101. The first type semiconductor layer 210, which is porous, may have the plurality of pores 2101. For example, the first type semiconductor layer 210 of the first light-emitting rod 201 and the third light-emitting rod 203 may have the plurality of pores 2101.

The plurality of pores 2101 may be empty spaces inside the first type semiconductor layer 210, and among the plurality of pores 2101, neighboring pores 2101 may be or may not be connected to each other. The size of the pores 2101 may vary. For example, the size of the pores 2101 may be about 1 nm to about 1 μm. The size of the pores 2101 may be about 10 nm to about 500 nm. The pores 2101 may be formed by an electrochemical wet etching method, etc. The size, density, etc. of the pores 2101 may be adjusted by a voltage, time, electrolyte, concentration, etc. applied to the electrochemical wet etching method.

The porosity of the first type semiconductor layer 210 may be defined by a ratio of the volume of the pores 2101 to the total volume of the first type semiconductor layer 210. The porosity of the first type semiconductor layer 210 may be 10% or more, 20% or more, 40% or less, or 80% or less. When the porosity is too high, a difficulty can be created regarding the mobility of carriers of the first type semiconductor layer 210, and when the porosity is too low, the density of a wavelength conversion cluster 211 to be described may become low, which may lead to a difficulty in wavelength conversion.

The second type semiconductor layer 230 may be a semiconductor layer doped with a second type dopant, which is different from the first type dopant. For example, the second type semiconductor layer 230 may include a p-type semiconductor. The second type semiconductor layer 230 may include III-V group p-type semiconductors, for example, p-GaN. The second type semiconductor layer 230 may have a single-layer or multi-layer structure. For example, the second type semiconductor layer 230 may include at least one semiconductor material from among InAlGaN, GaN, AlGaN, InGaN, AlN, and InN, and may be a semiconductor layer doped with a conductive dopant such as Mg, etc.

The active layer 220 may be arranged between the first type semiconductor layer 210 and the second type semiconductor layer 230. The active layer 220 may generate light through the bonding of electrons and holes, and may have a multi-quantum well (MQW) structure or a single-quantum well (SQW) structure. The active layer 220 may include III-V group semiconductors, for example, InGaN, GaN, AlGaN, AlInGaN, etc. A clad layer doped with a conductive dopant may be formed on and/or under the active layer 220. For example, the clad layer may be implemented as an AlGaN layer or an InAlGaN layer.

Each of the plurality of light-emitting rods 200 may further include, in addition to the first type semiconductor layer 210, the active layer 220, and the second type semiconductor layer 230, another clad layer and/or an electrode on and/or under each layer.

In general, a wavelength of light emitted from the active layer 220 may vary according to an amount of a material included in the active layer 220. The greater the content of indium (In) included in the active layer 220, the longer the wavelength of light emitted from the active layer 220 may be. For example, when the indium content of the active layer 220 is about 15%, the active layer 220 may emit blue light of about 450 nm, and when the indium content of the active layer 220 is about 25%, the active layer 220 may emit green light of about 520 nm. When the indium content of the active layer 220 is about 35%, the active layer 220 may emit red light of about 630 nm.

In general, a LED of about 100 μm×100 μm or greater may have high light efficiency. However, when the size of a LED is 100 μm or less, the light efficiency may decrease significantly. When the active layer 220 including AlGaInP emits red light, the external quantum efficiency (EQE) may decrease rapidly. For example, as the active layer 220 generating red light of about 630 nm has indium content of 35%, the EQE is expected to be 5% or less due to a defect caused by lattice mismatch between the active layer 220 and the first type semiconductor layer 210. In addition, when the active layer 220 includes InGaN, a blue shift phenomenon may occur as a result of increased current. The blue shift may be caused by the quantum stark effect according to a piezoelectric field. Moreover, there may be a full width at half maximum (FWHM) issue due to agglomeration of indium.

The indium content of the active layer 220 according to an embodiment may be 25% or less. For example, the indium content of the active layer 220 may be 15% of less, and the active layer 220 may generate ultraviolet light, blue light, or light having a wavelength of about 300 nm to about 500 nm. When the indium content of the active layer 220 is low, defects due to lattice mismatch between the first type semiconductor layer 210 and the active layer 220 may be reduced. In addition, a low indium content may lead to a reduction in blue shift phenomenon.

The active layer 220 of the light-emitting rods 200 according to an embodiment may include an InGaN-based nitride semiconductor. In the case of the light-emitting rod 200 having a width less than a length, when an InGaN-based nitride semiconductor is used as the active layer 220, a leakage current may be reduced as compared to an embodiment including an AlGaInP-based active layer 220.

The light-emitting rod 200 according to an embodiment may further include wavelength conversion clusters 211 embedded in the light-emitting rod 200 and converting light generated from the active layer 220 into light having a different wavelength. The wavelength conversion clusters 211 may be arranged in the first type semiconductor layer 210 which is porous. For example, the wavelength conversion cluster 211 may be arranged in the pores 2101 included in the first type semiconductor layer 210.

The active layer 220 may generate first light within the range of visible light or blue light, and the wavelength conversion clusters 211 may convert the first light generated from the active layer 220 into second light having a different wavelength from that of the first light. The second light may have a greater wavelength than the first light. The second light may be green light, red light, or light having a wavelength of about 490 nm to about 780 nm. As described above, the indium content needs to be high for the active layer 220 to generate blue light; however, high indium content may decrease light efficiency.

As the light-emitting rods 200 according to an embodiment use the active layer 220 having low indium content, the wavelength conversion cluster 211 embedded in the light-emitting rods 200 may convert the light generated from the active layer 220 into red light or green light.

The wavelength conversion clusters 211 may include a plurality of quantum dots. From among the plurality of quantum dots, neighboring quantum dots may be or may not be connected to each other. The plurality of quantum dots that are connected or not connected to each other in the pores 2101 of the first type semiconductor layer 210 may be agglomerated and referred to as a cluster. The connected quantum dots may be ligand-combined. The ratio of the quantum dots in the pores 2101 may be about 80% or 90% or more. Spaces in the pores 2101 other than the quantum dots may be empty or filled with a photoresist material.

The quantum dots may be formed of a nanometer-sized inorganic substance and have an energy bandgap of a specific wavelength, and thus said dots are able to output light of different wavelengths when they have absorbed light having a higher energy than the energy bandgap. The quantum dots may have a narrow emission wavelength band.

The quantum dots may have a core-shell structure including a core portion and a shell portion, or a particle structure without a shell. The core-shell structure may be a single-shell structure or a multi-shell structure, for example, a double-shell structure.

The quantum dots may include II-VI group semiconductors, III-V group semiconductors, IV-VI group semiconductors, IV group semiconductors, and/or graphene quantum dots. The quantum dots may include, for example, Cd, Se, Zn, S, and/or InP, and each quantum dot may have a diameter less than or equal to tens of nanometers, for example, 10 nm or less. The quantum dots may be excited by blue light or ultraviolet light according to a material or size thereof and emit red light or green light.

The light-emitting rod 200 may further include a wavelength selective transmissive layer 250 arranged on a lateral surface of the light-emitting rod 200. The wavelength selective transmissive layer 250 may surround at least a part of the lateral surface of the light-emitting rod 200. The wavelength selective transmissive layer 250 may transmit light of a particular wavelength from among incident light. For example, the wavelength selective transmissive layer 250 may reflect, from among incident light, first light L1 generated from the active layer 220 into the light-emitting rod 200 and transmit second light L2 whose wavelength has been converted by the wavelength conversion clusters 211 to the outside. In this manner, the light-emitting rod 200 may emit light whose wavelength has been converted by the wavelength conversion clusters 211 other than the light generated from the active layer 220. The active layer 220 may generate blue light or ultraviolet light, whereas the light-emitting rod 200 may emit blue light or green light.

The wavelength selective transmissive layer 250 may reflect the incident first light into the light-emitting rod 200 to reuse the first light such that the first light may be converted into the second light by the wavelength conversion cluster 211, and transmit the incident second light outside the light-emitting rod 200, thereby increasing the color purity of light emitted by the light-emitting rod 200.

The wavelength selective transmissive layer 250 may include a distributed Bragg reflector. For example, the wavelength selective transmissive layer 250 may include two layers having different refractive indexes from each other. The two layers may be alternately stacked repeatedly. Due to a refractive index difference between the two layers, light may be reflected from an interface of each layer, and the reflected light may cause interference. Each of the two layers may include silicon (Si), silicon nitride (Si₃N₄), silicon oxide (SiO₂), titanium oxide (TiO₂), etc. For example, one layer may include titanium (TiO₂), and another layer may include silicon oxide (SiO₂). By adjusting the thickness and/or stacking number of the two layers, the refractive index of the wavelength selective transmissive layer 250 in relation to the first light L1 and the transmittance relating to the second light L2 may be designed.

The wavelength selective transmissive layer 250 may include an insulating film instead of the distributed Bragg reflector. The insulating film may include an insulating material and may have a thickness of 50 nm or less. The insulating film may include hafnium dioxide (HfOx) and may have a thickness of 40 nm or less.

Another thin film layer may be arranged between the wavelength selective transmissive layer 250 and the light-emitting rod 200. The thin film layer may include AlN and may have a thickness of 20 nm or less.

The light-emitting rod 200 may further include a reflective layer 240 arranged at an end of the light-emitting rod 200. The reflective layer 240 may be arranged on a lower surface of the light-emitting rod 200, i.e., under the second type semiconductor layer 230. The reflective layer 240 may reflect incident light into the light-emitting rod 200. For example, the reflective layer 240 may reflect incident first light and/or second light into the light-emitting rod 200. The reflective layer 240 may reflect the first light into the light-emitting rod 200 such that the first light is converted into the second light by the wavelength conversion cluster 211 to increase the color conversion rate. The reflective layer 240 may reflect the second light into the light-emitting rod 200 such that the second light is emitted to the outside through the wavelength selective transmissive layer 250 and control an emission direction of the second light.

The reflective layer 240 may include a material having a high reflectivity with respect to the first light and the second light. As the reflective layer 240 is arranged on the second type semiconductor layer 230, the reflective layer 240 may include a conductive material which enables electric connection with an electrode to be described. The reflective layer 240 may include a metal material having a high reflectivity and conductivity, for example, Ag, Au, Pt, Ni, Cr, and/or Al; however, the disclosure is not limited thereto.

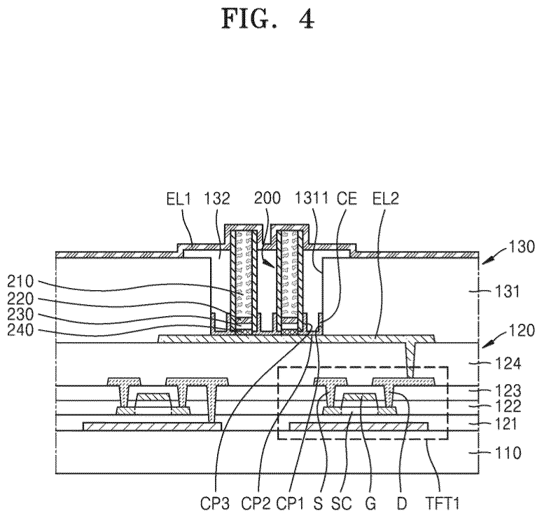

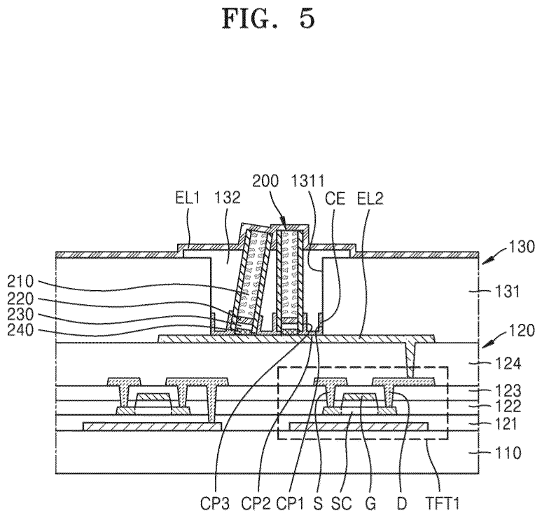

FIG. 4 is an enlarged view of a part of the light-emitting device structure 10 of FIG. 1, according to an embodiment. FIG. 5 is another enlarged view of a part of the light-emitting device structure 10 of FIG. 1, according to an embodiment.

Referring to FIGS. 1 through 4, in the light-emitting device structure 10 according to an embodiment, each of the plurality of light-emitting rods 200 may be in an upright position (or upright posture) corresponding to the thickness direction of the substrate 110. For example, the first light-emitting rod 201 may be in an upright position corresponding to the thickness direction of the substrate 110. The second light-emitting rod 202 may be in an upright position corresponding to the thickness direction of the substrate 110. The third light-emitting rod 203 may be in an upright position corresponding to the thickness direction of the substrate 110.

For example, the display device layer 130 may further include a bank layer 131 having a groove 1311 into which at least a part of the light-emitting rods 200 may be insertable. The bank layer 131 may be arranged to surround a lateral surface of the light-emitting rod 200 inserted into the groove 1311.

The groove 1311 of the bank layer 131 may have a first width and a second height. The light-emitting rod 200 may have a first diameter and a first height. The second height may be less than the first height such that a part of the light-emitting rod 200 protrudes from the bank layer 131.

The first width of the groove 1311 may be greater than the first diameter of the light-emitting rod 200. The groove 1311 of the bank layer 131 may arranged to avoid falling of the light-emitting rod 200. For example, the second height of the groove 1311 may be greater than ¼ of the first height of the light-emitting rod 200.

At least one light-emitting rod 200 may be arranged in the groove 1311. For example, a plurality of light-emitting rods 200 emitting the same light may be arranged in the groove 1311. For example, two light-emitting rods 200 may be arranged in the groove 1311. However, the number of the light-emitting rods 200 arranged in the groove 1311 is not limited thereto and may be 1 or 3 or more.

Each of the plurality of light-emitting rods 200 arranged upright in the groove 1311 may be electrically connected to the semiconductor device layer 120. The light-emitting device structure 10 may include a lower electrode EL2 electrically connected to a lower portion of the light-emitting rods 200. The lower electrode EL2 may be connected to the driving transistors TFT1 of the semiconductor device layer 120. The lower electrode EL2 may penetrate the protective layer 124 and be connected to the driving transistors TFT1.

The lower electrode EL2 may include a metal material having excellent conductivity, for example, at least one of Au, Ag, Cu, Zn, Al, In, Ti, Si, Ge, Sn, Mg, Ta, Cr, W, Ru, Rh, Ir, Ni, Pd, and Pt.

The light-emitting device structure 10 may further include a contact electrode CE in contact with the light-emitting rods 200 and the lower electrode EL2. The contact electrode CE may include a metal material having excellent conductivity, for example, at least one of Au, Ag, Cu, Zn, Al, In, Ti, Si, Ge, Sn, Mg, Ta, Cr, W, Ru, Rh, Ir, Ni, Pd, and Pt.

The contact electrode CE may include a first contact portion CP1 in contact with an inner wall of the groove 1311, a second contact portion CP2 in contact with an upper surface of the lower electrode EL2, and a third contact portion CP3 in contact with a lower lateral surface of the light-emitting rod 200. The electrical connection between the lower electrode EL2 and the light-emitting rod 200 may be secured by the contact electrode CE.

The light-emitting device structure 10 may further include an upper electrode EL1 electrically connected to an upper portion of the light-emitting rods 200.

The upper electrode EL1 may be arranged to be in contact with an upper surface and an upper lateral surface of the light-emitting rod 200. The upper electrode EL1 may extend along with the upper surface of the bank layer 131 and an insulating layer 132. The upper electrode EL1 may be a transparent electrode through which light may be transmitted. The upper electrode EL1 may include, for example, a transparent conductive material, such as indium tin oxide (ITO), indium zinc oxide (IZO), etc. However, the disclosure is not limited thereto. The light transmittance of the upper electrode EL1 may be greater than 80%.

For example, the second type semiconductor layer 230 of the light-emitting rod 200 may be electrically connected to the lower electrode EL2, and the first type semiconductor layer 210 may be electrically connected to the upper electrode EL1. The reflective layer 240 may be arranged between the lower electrode EL2 and the second type semiconductor layer 230.

The light-emitting device structure 10 may further include the insulating layer 132 filled in the groove 1311 to maintain the upright position of the light-emitting rod 200. The light-emitting rods 200 may be arranged to protrude from the upper surface of the insulating layer 132. The insulating layer 132 may contact and support the lateral surface of the light-emitting rod 200.

The upper electrode EL1 may be arranged to be in contact with the plurality of light-emitting rods 200 protruding from the upper surface of the insulating layer 132. The insulating layer 132 may be arranged between the contact electrode CE and the upper electrode EL1. The insulating layer 132 may block the contact of the upper electrode EL1 with the lower electrode EL2 and the contact electrode CE.

The first type semiconductor layer 210 of each of the plurality of light-emitting rods 200 arranged upright in the groove 1311 of the bank layer 131 may be directed upwards. For example, the light-emitting rod 200 may be arranged in a manner that the first type semiconductor layer 210 is located on the active layer 220. The reflective layer 240 may be arranged under the second type semiconductor layer 230. Accordingly, the light generated from the active layer 220 may be guided to pass through the wavelength conversion cluster 211.

FIG. 4 illustrates an example of upright position of the light-emitting rods 200 in which the plurality of light-emitting rods 200 are arranged in a direction parallel with the thickness direction of the substrate 110. However, the upright position of the light-emitting rods 200 according to an embodiment is not limited thereto, and the arrangement may vary to the extent that the length direction of the light-emitting rods 200 and the thickness direction of the substrate 110 form an acute angle. For example, as illustrated in FIG. 5, the upright position of the light-emitting rod 200 may be position to be inclined relative to the thickness direction of the substrate 110.

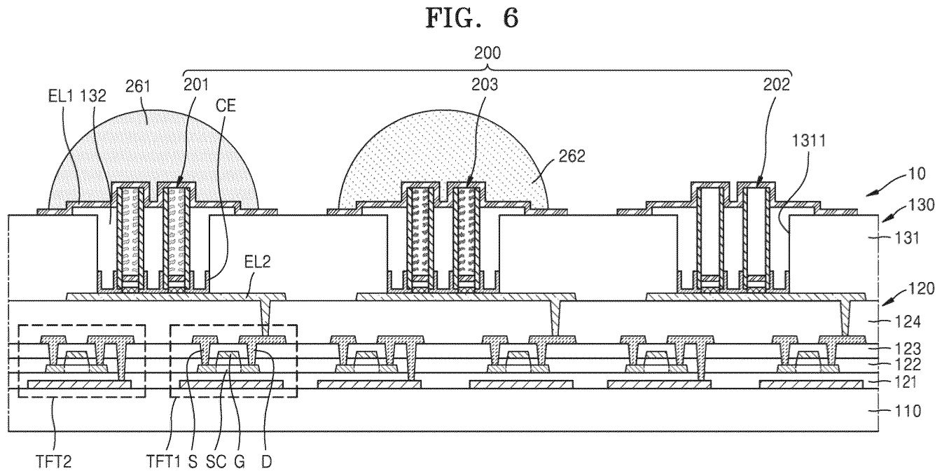

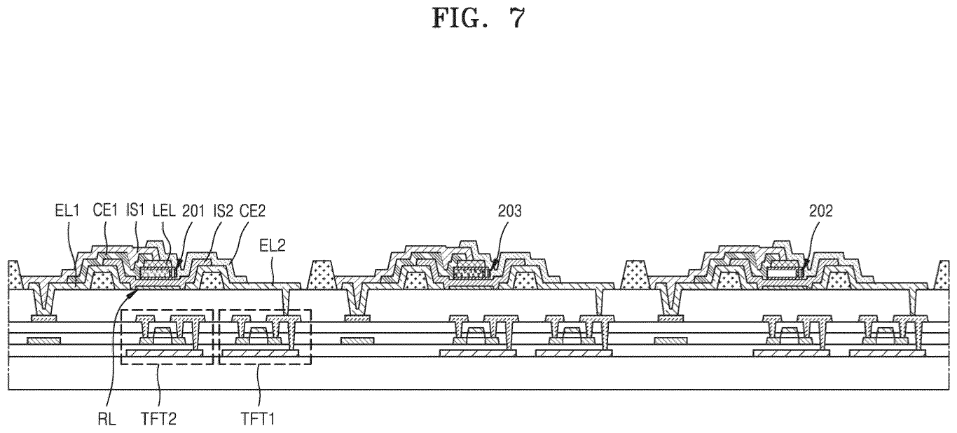

FIG. 6 is a schematic cross-sectional view of the light-emitting device structure 10 according to another embodiment. FIG. 7 is a schematic cross-sectional view of the light-emitting device structure 10 according to another embodiment.

Referring to FIG. 6, the light-emitting device structure 10 according to an embodiment may further include a color filter (261 and 262). For examples, the color filter (261 and 262) may be arranged on at least some of the plurality of light-emitting rods 200. For example, the color filter 261 may be arranged on the first light-emitting rod 201, and another color filter 262 may be arranged on the third light-emitting rod 203.

The color filters 261 and 262 may selectively transmit light emitted from the light-emitting rods 200 thereunder. The color filter 261 arranged on the first light-emitting rod 201 may selectively transmit light of the first wavelength and may absorb light having a wavelength other than the first wavelength. The color filter 262 arranged on the third light-emitting rod 203 may selectively transmit light of the third wavelength and may absorb light having a wavelength other than the third wavelength.

The embodiments of the light-emitting device structure 10 provided so far illustrate an example in which the plurality of light-emitting rods 200 are arranged in an upright position. However, the arrangement of the light-emitting rods 200 of the light-emitting device structure 10 according to an embodiment is not limited thereto. For example, as illustrated in FIG. 7, the plurality of light-emitting rods 200 of the light-emitting device structure 10 may be in a lying position in a direction perpendicular to the thickness direction of the substrate 110. The light-emitting device structure 10 may further include a reflective layer RL arranged under the light-emitting rod 200 and a light extract layer LEL arranged on the light-emitting rod 200. The lower electrode EL2 and the upper electrode EL1 may be arranged horizontally at respective ends of the light-emitting rod 200 and may be connected to the respective ends of the light-emitting rod 200 through the contact electrodes CE1 and CE2. Insulating layers IS1 and IS2 may be respectively arranged between the contact electrodes CE1 and CE2, the lower electrode EL2, and the upper electrode EL1.

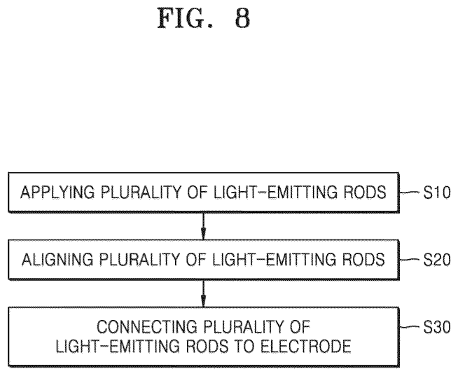

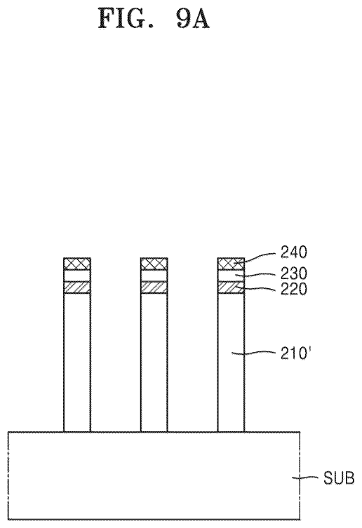

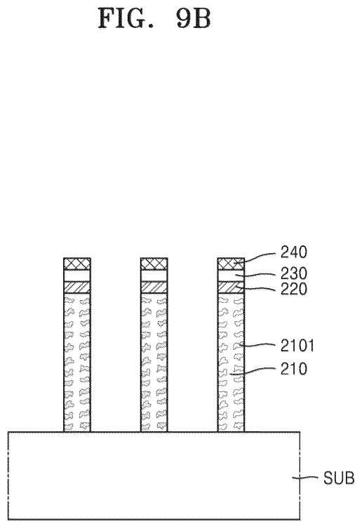

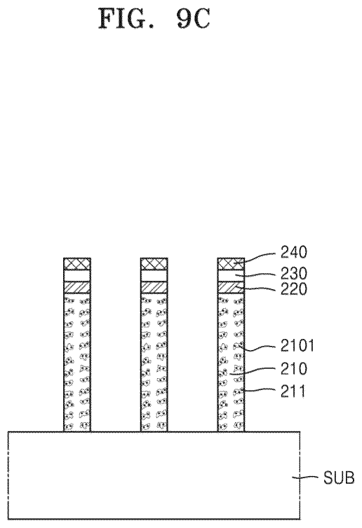

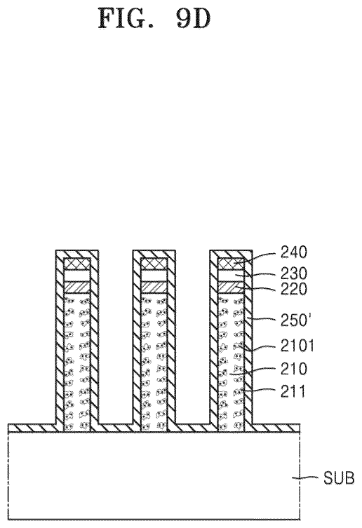

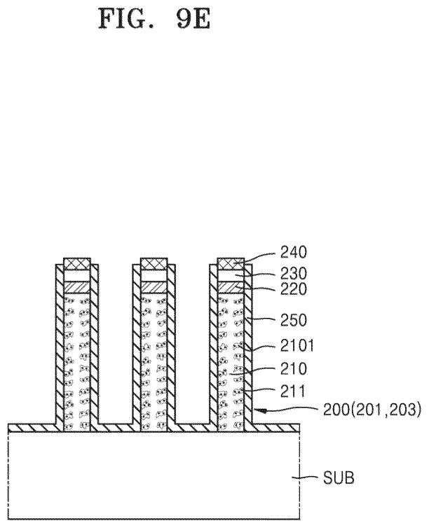

FIG. 8 is a flowchart illustrating a method of manufacturing the light-emitting device structure 10 according to an embodiment. FIGS. 9A to 9E are each a view illustrating a method of manufacturing a light-emitting device of the light-emitting device structure 10, according to an embodiment.

Referring to FIG. 8, a method of manufacturing the light-emitting device structure 10 according to an embodiment may include arranging the plurality of light-emitting rods 200 (S10), aligning the plurality of light-emitting rods 200 (S20), and connecting the plurality of light-emitting rods 200 to an electrode (S30).

The method of manufacturing the light-emitting device structure 10 may further include preparing the plurality of light-emitting rods 200 before applying the plurality of light-emitting rods 200.

In the prepared light-emitting rods 200, the first type semiconductor layer 210 may have a plurality of pores 2101, and the wavelength conversion cluster 211 converting light generated from the active layer 220 into light having a different wavelength may be arranged in the plurality of pores 2101.

To manufacture the light-emitting rods 200, as illustrated in FIG. 9A, a first type semiconductor layer 210′, the active layer 220, and the second type semiconductor layer 230 may be sequentially formed on a substrate SUB. The substrate SUB may be the substrate 110 for growth of the light-emitting rods 200. The substrate SUB may include various materials used in general semiconductor processes. For example, a silicon substrate 110 or a sapphire substrate 110 may be used as the substrate SUB.

The first type semiconductor layer 210′, the active layer 220, and the second type semiconductor layer 230 may be formed by metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), etc.

The reflective layer 240 may be formed on the second type semiconductor layer 230. The reflective layer 240 may be formed by MOCVD, CVD, PECVD, etc.

As illustrated in FIG. 9B, the pores 2101 may be formed in the first type semiconductor layer 210. The pores 2101 of the first type semiconductor layer 210 may be formed by using an electrochemical wet etching method. The electrochemical wet etching method may include an etching method by potential difference, a photoelectrochemical etching method, etc. An etching solution may include oxalic acid, nitric acid, odium nitrate, etc.; however, the disclosure is not limited thereto.

The density of the pores 2101 of the first type semiconductor layer 210, i.e., the porosity thereof may be adjusted by the voltage applied in the perforation process, perforation time, etching solution used in the perforation process, doping concentration of the first type semiconductor layer 210, etc. For example, when the perforation of the first type semiconductor layer 210 is performed as a method of etching silicon (Si) included in the first type semiconductor layer 210, the higher the doping concentration of silicon is, the higher the porosity of the first type semiconductor layer 210 may be. When the active layer 220 and the second type semiconductor layer 230 are not doped with silicon, the active layer 220 and the second type semiconductor layer 230 may not be perforated.

As illustrated in FIG. 9C, the wavelength conversion cluster 211 may be formed in the light-emitting rod 200. The light-emitting rod 200 may be immersed into a solution including quantum dots and may be further subjected to electrolytic plating, photoresist process, electrophoretic deposition, etc. such that the quantum dots may enter and be embedded in the light-emitting rod 200.

The quantum dots may enter into the first type semiconductor layer 210 and may be arranged in the pores 2101 of the first type semiconductor layer 210. From among the quantum dots arranged in the pores 2101 of the first type semiconductor layer 210, neighboring quantum dots that are connected or not connected to each other may be agglomerated in the pores 2101 and referred to as a cluster. The connected quantum dots may be ligand-combined. The ratio of the quantum dots in the pores 2101 may be about 80% or 90% or more. Spaces in the pores 2101 other than the quantum dots may be empty or filled with a photoresist material. After the quantum dots are arranged in the pores 2101, a solvent may be removed, or a photoresist material may still remain.

As illustrated in FIG. 9D, an insulating film 250′ may be formed on the light-emitting rod 200. The insulating film 250′ may include the same material as the wavelength selective transmissive layer 250 illustrated in FIG. 1. The insulating film 250′ may be formed to cover the exposed area of the reflective layer 240 and the light-emitting rod 200. For example, the insulating film 250′ may be formed to cover the upper surface and the lateral surface of the reflective layer 240 and the lateral surface of the light-emitting rod 200.

As illustrated in FIG. 9E, the wavelength selective transmissive layer 250 may be formed by etching a partial area of the insulating film 250′. Then, the light-emitting rod 200 may be separated from the substrate SUB. Through this, the plurality of light-emitting rods 200 in which the wavelength conversion cluster 211 including the quantum dots is arranged in the first type semiconductor layer 210 may be prepared.

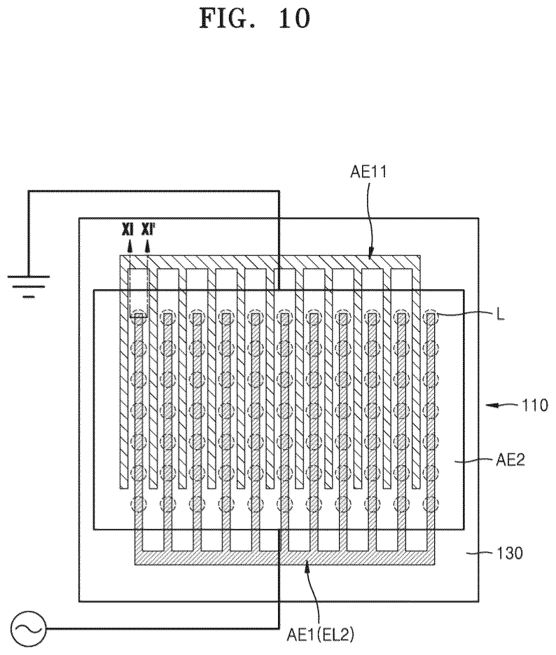

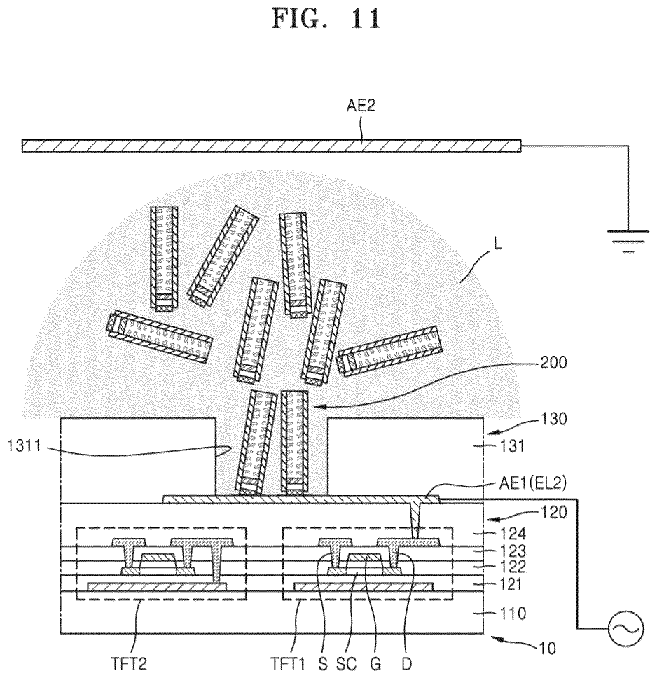

FIG. 10 is a plan view illustrating a process of applying and aligning the plurality of light-emitting rods on the substrate 110, and FIG. 11 is a cross-sectional view taken along line XI-XI′ line of FIG. 10.

Referring to FIGS. 10 and 11, the plurality of light-emitting rods 200 may be arranged on one substrate 110. For example, the semiconductor device layer 120 may be arranged on the substrate 110, and the plurality of light-emitting rods 200 may be arranged on the semiconductor device layer 120.

The plurality of light-emitting rods 200 may be provided on the semiconductor device layer 120 together with liquid L. For example, the plurality of light-emitting rods 200 may be applied together with the liquid L on the bank layer 131 including the groove 1311.

The liquid L may be any liquid which would not corrode or damage the plurality of light-emitting rods 200. For example, the liquid L may include one of water, ethanol, alcohol, ketone, acetone, sodium chloride, flux, and organic solvent, or one or more combinations thereof. The organic solvent may include, for example, isopropyl alcohol (IPA). The type of the liquid is not limited thereto, and various other liquids may be used as well.

The liquid L may be provided by, for example, a spraying method, a dispensing method, an inkjet-dot method, etc., or the liquid L may be flowed to the substrate 110.

Next, an electric field may be applied around the plurality of light-emitting rods 200 to align the plurality of light-emitting rods 200 in a certain direction. For example, the plurality of light-emitting rods 200 arranged on the substrate 110 may be aligned in a particular posture determined by electrophoresis or dielectrophoresis. For example, some of the plurality of light-emitting rods 200 may be arranged in an upright position in the groove 1311 of the bank layer 131.

An alignment apparatus for applying an electric field around the plurality of light-emitting rods 200 may include a lower alignment electrode AE1 and an upper alignment electrode AE2. A certain voltage may be applied to the lower alignment electrode AE1 and the upper alignment electrode AE2.

The lower alignment electrode AE1 may be arranged under the light-emitting rod 200, and the upper alignment electrode AE2 may be arranged on the light-emitting rod 200. The lower electrode EL2 arranged under the bank layer 131 may be used as the lower alignment electrode AE1.

For example, through the dielectrophoresis, to align the plurality of light-emitting rods 200 in a certain posture, an alternating current voltage and a direct current voltage or an alternating current voltage may be applied to the lower alignment electrode AE1 and the upper alignment electrode AE2 of the alignment apparatus. A voltage obtained by adding direct current offset to a sine wave alternating current voltage may be applied to the lower and upper alignment electrodes AE1 and AE2 of the alignment apparatus. Or, an alternating current voltage without a direct current offset may be applied to the lower and upper alignment electrodes AE1 and AE2 of the alignment apparatus. Or, a pulse-type direct current voltage may be applied to the alignment electrodes of the alignment apparatus such that the alignment electrodes have a certain frequency.

Alternatively, through the electrophoresis, the plurality of light-emitting rods 200 may be aligned in a certain posture by applying a direct current voltage to the lower alignment electrode AE1 and the upper alignment electrode AE2 of the alignment apparatus. By the applied direct current voltage, an electric field may be formed in a certain direction.

To align the light-emitting rods 200 by the electrophoresis, for example, the light-emitting rods 200 may be coated by a metal layer. The metal layer may include at least one of gold (Au), silver (Ag), aluminum (Al), and tantalum (Ta). The metal layer may be coated through wet coating or atomic layer deposition (ALD). However, the coating method of the metal layer is not limited thereto, and various other methods according to a material, etc. of the metal layer may be used. The liquid L used when applying the light-emitting rods 200 coated with the metal layer may include water and sodium chloride. The amount of sodium chloride mixed with the liquid L may be about 0.2 mM to about 2.0 mM. For example, the amount of sodium chloride mixed with the liquid L may be about 0.3 mM to about 0.7 mM.

The arranging of the plurality of light-emitting rods 200 and aligning of the plurality of light-emitting rods 200 in a certain posture may be repeated. For example, the arranging of the plurality of first light-emitting rod 201, the arranging of the plurality of second light-emitting rod 202, and the arranging of the plurality of third light-emitting rod 203 may be performed sequentially or simultaneously. Accordingly, the plurality of first to third light-emitting rods 201, 202, and 203 may be arranged at different positions from each other.

For example, the aligning of the plurality of first light-emitting rod 201, the aligning of the plurality of second light-emitting rod 202, and the aligning of the plurality of third light-emitting rod 203 may be performed sequentially or simultaneously. Accordingly, the plurality of first to third light-emitting rods 201, 202, and 203 may be aligned at different positions from each other in a certain posture. In the first, second, and third alignments, a common upper alignment electrode AE2 may be used, and lower alignment electrodes AE1 that are different from each other may be used.

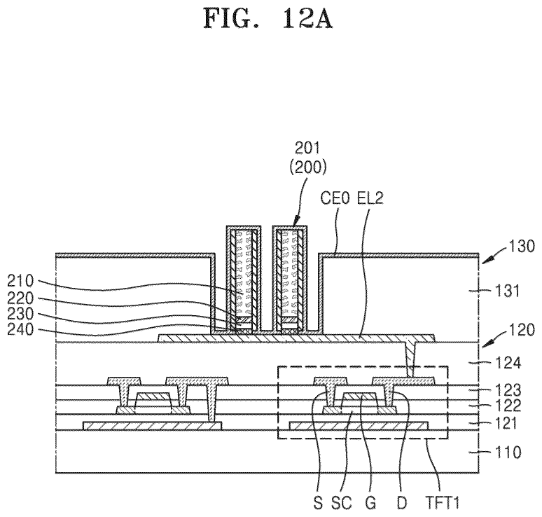

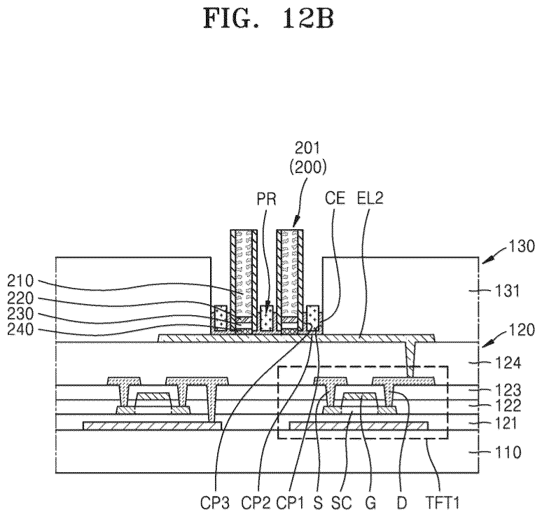

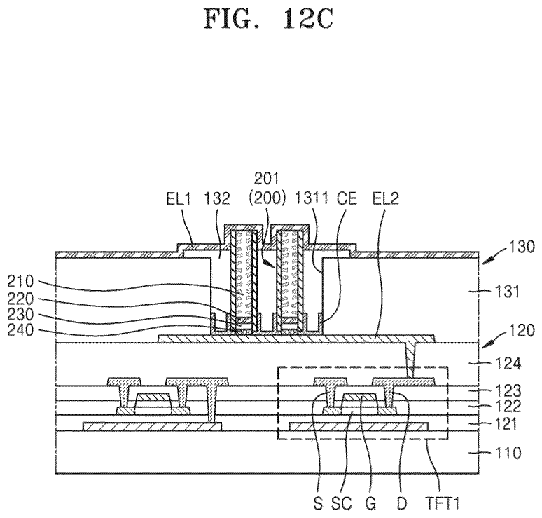

FIGS. 12A to 12C are each a view illustrating a process of connecting an electrode to the light-emitting rod 200 in the light-emitting device structure 10, according to an embodiment.

Referring to FIGS. 12A and 12B, in the light-emitting device structure 10 according to an embodiment, the plurality of light-emitting rods 200 may be in an upright position. For example, the plurality of first light-emitting rods 201 may be in an upright position. In the connecting of the light-emitting rod 200 to the electrode, the contact electrode CE in contact with the lower portion of the light-emitting rod 200 and the lower electrode EL2 may be formed.

For example, as illustrated in FIG. 12A, a contact electrode layer CE0 may be deposited on the light-emitting device structure 10.

The contact electrode layer CE0 may be deposited on the upper surface of the bank layer 131, the inner surface of the groove 1311, a part of the upper surface of the lower electrode EL2, and the lateral surfaces and the uppers surfaces of the plurality of light-emitting rods 200. The contact electrode layer CE0 may include a metal material having excellent conductivity, for example, at least one of Au, Ag, Cu, Zn, Al, In, Ti, Si, Ge, Sn, Mg, Ta, Cr, W, Ru, Rh, Ir, Ni, Pd, and Pt.

The width of the groove 1311 of the bank layer 131 may be greater than the width of the light-emitting rod 200. The width of the groove 1311 of the bank layer 131 may be greater than double the width of the light-emitting rod 200. The lateral surface of the groove 1311, the lateral surface of the light-emitting rod 200, and the lateral surface of the adjacent light-emitting rod 200 may be apart from each other.

Referring to FIG. 12B, to pattern the contact electrode layer CE0 in a certain shape, a photoresistor PR may be arranged between the lateral surface of the groove 1311 and the lateral surface of the light-emitting rod 200 and between the lateral surface of the light-emitting rod 200 and the lateral surface of the adjacent light-emitting rod 200. Then, the contact electrode CE may be formed in a certain shape by removing the contact electrode layer CE0 exposed outside of the photoresistor PR. The contact electrode layer CE0 may be removed by wet etching.

The contact electrode CE may include the first contact portion CP1 in contact with the inner wall of the groove 1311, the second contact portion CP2 in contact with the upper surface of the lower electrode EL2, and the third contact portion CP3 in contact with the lower lateral surface of the light-emitting rod 200. The electrical connection between the lower electrode EL2 and the light-emitting rod 200 may be secured by the contact electrode CE.

Referring to FIG. 12C, the photoresistor PR may be removed by ashing. Next, the insulating layer 132 may be filled inside the groove 1311 to cover the contact electrode CE. The insulating layer 132 may be filled in the groove 1311 to expose the upper portion of the light-emitting rod 200. The upper portion of the light-emitting rod 200 may protrude from the insulating layer 132.

The insulating layer 132 may be polymer. However, the material of the insulating layer 132 is not limited thereto, and any insulating material which may maintain the arrangement of the light-emitting rods 200 and block the electrical contact with an electrode may be used.

Then, the upper electrode EL1 electrically connected to the upper portion of the plurality of light-emitting rods 200 may be formed. When the insulating layer 132 is filled inside the groove 1311, the upper electrode EL1 may be arranged on the light-emitting rod 200. For example, the upper electrode EL1 may be arranged on the light-emitting rod 200 through deposition. The upper electrode EL1 may be arranged to surround the upper portion of the light-emitting rod 200 which protrudes outside the insulating layer 132. For example, the upper electrode EL1 may be arranged along the shapes of the upper surface of the bank layer 131, the upper surface of the insulating layer 132, and the upper portion of the light-emitting rod 200.

The upper electrode EL1 may be a transparent electrode. The upper electrode EL1 may include, for example, a transparent conductive material, such as indium tin oxide (ITO), indium zinc oxide (IZO), etc. However, the disclosure is not limited thereto. The light transmittance of the upper electrode EL1 may be greater than 80%.

The display apparatuses described above may be applied to various electronic apparatuses having a display function.

A light-emitting device structure, a display apparatus, and a method of manufacturing the light-emitting device structure according to an embodiment may provide a display having high resolution and high efficiency.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light-emitting device structure comprising:
a substrate;
a semiconductor device layer on the substrate, the semiconductor device layer comprising a plurality of semiconductor devices; and
a display device layer comprising a plurality of light-emitting rods on the semiconductor device layer, wherein the plurality of light-emitting rods are connected to the plurality of semiconductor devices,
wherein the plurality of light-emitting rods comprises:
a first light-emitting rod configured to emit light comprising a first wavelength;
a second light-emitting rod configured to emit light comprising a second wavelength which is different from the first wavelength; and
a third light-emitting rod configured to emit light comprising a third wavelength which is different from the first wavelength and the second wavelength,
wherein each of the plurality of light-emitting rods comprises a first type semiconductor layer, an active layer, and a second type semiconductor layer, which are sequentially arranged, and
wherein, in at least one of the plurality of light-emitting rods, the first type semiconductor layer comprises a pore, and a wavelength conversion cluster in the pore, wherein the wavelength conversion cluster is configured to convert light generated from the active layer into light having a wavelength different from a wavelength of the light generated from the active layer.

2. The light-emitting device structure of claim 1,
wherein each of the plurality of light-emitting rods is in an upright position corresponding to a thickness direction of the substrate,
wherein the display device layer further comprises a bank layer comprising a groove, and
wherein at least a part of each of the plurality of light-emitting rods is in the groove.

3. The light-emitting device structure of claim 2,
wherein each of the plurality of light-emitting rods comprises a first diameter and a first height,
wherein the groove comprises a first width and a second height, and
wherein the first width is greater than the first diameter, and the second height is greater than one-fourth of the first height.

4. The light-emitting device structure of claim 2, further comprising:
a lower electrode connected to a lower portion of each of the plurality of light-emitting rods; and
an upper electrode connected to an upper portion of each of the plurality of light-emitting rods.

5. The light-emitting device structure of claim 4, further comprising a contact electrode in contact with the lower electrode and each of the plurality of light-emitting rods,
wherein the contact electrode comprises a first contact portion in contact with a lateral surface of the groove, a second contact portion in contact with an upper surface of the lower electrode, and a third contact portion in contact with a lower lateral surface of each of the plurality of light-emitting rods.

6. The light-emitting device structure of claim 4,
wherein the bank layer further comprises an insulating layer in the groove, and
wherein the insulating layer is configured to maintain the upright position of each of the plurality of light-emitting rods.

7. The light-emitting device structure of claim 6,
wherein a portion of each of the plurality of light-emitting rods partially protrudes from an upper surface of the insulating layer, and
wherein the upper electrode is in contact with the portion of each of the plurality of light-emitting rods protruding from the upper surface of the insulating layer.

8. The light-emitting device structure of claim 2,
wherein for each of the plurality of light-emitting rods, the first type semiconductor layer is on the active layer, and
wherein each of the plurality of light-emitting rods further comprises a reflective layer under the second type semiconductor layer.

9. The light-emitting device structure of claim 2, further comprising: a color filter configured to selectively transmit light,
wherein the color filter is on at least one of the plurality of light-emitting rods.

10. The light-emitting device structure of claim 2, further comprising: a wavelength selective transmissive layer configured to selective transmit light according to a wavelength,
wherein the wavelength selective transmissive layer is on a lateral surface of at least one of the plurality of light-emitting rods.

11. The light-emitting device structure of claim 1,
wherein for each of the plurality of light-emitting rods, a ratio of a length of the light-emitting rod to a width of the light-emitting rod is 3 or more, and
wherein the width is 100 μm or less.

12. A display apparatus comprising:
a light-emitting device structure, wherein the light-emitting device structure comprises:
a substrate;
a semiconductor device layer on the substrate, the semiconductor device layer comprising a plurality of semiconductor devices;
a display device layer comprising a plurality of light-emitting rods on the semiconductor device layer, wherein the plurality of light-emitting rods are connected to the plurality of semiconductor devices,
wherein the plurality of light-emitting rods comprises:
a first light-emitting rod configured to emit light comprising a first wavelength;
a second light-emitting rod configured to emit light comprising a second wavelength which is different from the first wavelength; and
a third light-emitting rod configured to emit light comprising a third wavelength which is different from the first wavelength and the second wavelength,
wherein each of the plurality of light-emitting rods comprises a first type semiconductor layer, an active layer, and a second type semiconductor layer, which are sequentially arranged,
wherein, in at least one of the plurality of light-emitting rods, the first type semiconductor layer comprises a pore and a wavelength conversion cluster in the pore, and
wherein the wavelength conversion cluster is configured to convert light generated from the active layer into light having a wavelength different from a wavelength of the light generated from the active layer.

13. The display apparatus of claim 12, wherein the display device layer further comprises a bank layer comprising a groove, and at least a part of each of the plurality of light-emitting rods is in the groove, the bank layer further comprises an insulating layer in the groove, wherein the insulating layer is configured to maintain each of the plurality of light-emitting rods in an upright position corresponding to a thickness direction of the substrate.

14. The display apparatus of claim 12, wherein for each of the plurality of light-emitting rods, the first type semiconductor layer is on the active layer, and each of the plurality of light-emitting rods further comprises a reflective layer under the second type semiconductor layer.

15. The display apparatus of claim 12, where the light-emitting device structure further comprises:
a wavelength selective transmissive layer configured to selective transmit light according to a wavelength,
wherein the wavelength selective transmissive layer is on a lateral surface of at least one of the plurality of light-emitting rods.

16. The display apparatus of claim 13, wherein each of the plurality of light-emitting rods comprises a first diameter and a first height, the groove comprises a first width and a second height, and the first width is greater than the first diameter, and the second height is greater than one-fourth of the first height.

17. A method of manufacturing a light-emitting device structure, the method comprising:
arranging a plurality of light-emitting rods on a semiconductor device layer provided on a substrate;
aligning the plurality of light-emitting rods in a first direction by applying an electric field around the plurality of light-emitting rods; and
connecting the plurality of light-emitting rods to an electrode,
wherein at least one of the plurality of light-emitting rods includes a first type semiconductor layer comprising a pore, and a wavelength conversion cluster in the pore, and
wherein the wavelength conversion cluster is configured to convert light generated from an active layer of the at least one of the plurality of light-emitting rods into light having a wavelength different from a wavelength of the light generated from the active layer.

18. The method of claim 17,
wherein the arranging the plurality of light-emitting rods on the semiconductor device layer comprises applying a liquid including the plurality of light-emitting rods on a bank layer comprising a groove configured to receive the plurality of light-emitting rods, and
wherein the aligning the plurality of light-emitting rods further comprises arranging the plurality of light-emitting rods in the groove in an upright position corresponding to a thickness direction of the substrate using the electric field.

19. The method of claim 18, wherein the connecting the plurality of light-emitting rods to the electrode comprises:
forming a contact electrode in contact with a lower portion of the plurality of light-emitting rods and a lower electrode connected to a semiconductor device of the semiconductor device layer;
filling the groove with an insulating layer which covers the contact electrode; and
forming an upper electrode connected to an upper portion of each of the plurality of light-emitting rods.

20. A light-emitting device structure comprising:
a semiconductor device layer comprising a plurality of semiconductor devices; and
a display device layer comprising a plurality of light-emitting rods on the semiconductor device layer,
wherein the plurality of light-emitting rods comprises:
a first light-emitting rod configured to emit red light;
a second light-emitting rod configured to emit green light; and
a third light-emitting rod configured to emit blue light,
wherein each of the plurality of light-emitting rods comprises a quantum well, at least one of the first light-emitting rod, the second light-emitting rod, and the third light-emitting rod comprises quantum dots, and at least one of the first light-emitting rod, the second light-emitting rod, and the third light-emitting rod lacks quantum dots, and
wherein the plurality of light-emitting rods extends in a same direction.
